(19) United States
(12) Patent Application Publication
(10) Pub. No.: US 2016/0334707 A1
(43) Pub. Date: Nov. 17, 2016

(54) NEGATIVE PHOTOSENSITIVE RESIN COMPOSITION, CURED RESIN FILM, PARTITION WALLS AND OPTICAL ELEMENT

(71) Applicant: Asahi Glass Company, Limited, Chiyoda-ku (JP)

(72) Inventors: Yusuke NAGAI, Chiyoda-ku (JP); Hideyuki TAKAHASHI, Chiyoda-ku (JP); Masayuki KAWASHIMA, Chiyoda-ku (JP)

(73) Assignee: Asahi Glass Company, Limited, Chiyoda-ku (JP)

(21) Appl. No.: 15/222,031

(22) Filed: Jul. 28, 2016

Related U.S. Application Data
(63) Continuation of application No. PCT/JP2015/054323, filed on Feb. 17, 2015.

(30) Foreign Application Priority Data
Feb. 18, 2014 (JP) 2014-028800

(51) Int. Cl. G03F 7/075; H01L 51/42; H01L 51/05; H01L 51/00; H01L 51/50

(52) U.S. Cl. CPC G03F 7/0752; H01L 51/0005; H01L 51/0012; H01L 51/5012; H01L 51/0566; H01L 51/4253; H01L 2251/5392

(57) ABSTRACT

To provide a negative photosensitive resin composition for an optical element having good ink repellency and capable of reducing a residue at opening sections, a cured resin film for an optical element having good ink repellency, partition walls for an optical element capable of forming a high-precision pattern, and an optical element having such partition walls. A negative photosensitive resin composition comprising a photocurable alkali-soluble resin or alkali-soluble monomer (A), a photopolymerization initiator (B), a reactive ultraviolet absorber (C), a polymerization inhibitor (D), and an ink repellent (E); a cured film and partition walls formed by using the negative photosensitive resin composition; or an organic EL element, a quantum dot display, a TFT array, or a thin-film solar cell, having such partition walls positioned between a plurality of dots and their adjacent dots on a substrate surface.

### TECHNICAL FIELD

The present invention relates to a negative photosensitive resin composition, a cured resin film, partition walls and an optical element, to be used for an organic EL element, a quantum dot display, a TFT array or a thin film solar cell.

### BACKGROUND ART

In the production of an optical element such as an organic EL (Electro-Luminescence) element, a quantum dot display, a TFT (Thin Film Transistor) array or a thin-film solar cell, a method for pattern printing an organic layer such as a luminescent layer in the form of dots by an ink-jet (IJ) method, may be employed. In such a method, partition walls are formed along the profiles of dots to be formed, and an ink containing the material for the organic layer is injected into compartments (hereinafter referred to also as “opening sections”) defined by the partition walls, followed by e.g. drying and/or heating, to form dots in a desired pattern.

At the time of pattern printing by the ink-jet (IJ) method, the top surface of the partition walls are required to have ink repellency in order to prevent mixing of the ink between the adjacent dots and in order to uniformly apply the ink in forming the dots. On the other hand, the opening sections for forming dots as defined by the partition walls including the side surfaces of the partition walls are required to have ink-philicity. Therefore, in order to obtain partition walls having ink repellency on the top surface, a method has been known to form partition walls corresponding to the pattern of dots by a photolithography method employing a photosensitive resin composition having an ink repellent incorporated.

For example, Patent Document 1 discloses a method for making the top surface of partition walls to be ink repellent in forming partition walls of an image display element, of which the cross-sectional shape is an inverse tapered shape for the purpose of e.g. preventing short circuit in an organic EL element or the like. In Patent Document 1, in order to obtain the inverse tapered shape, a method is employed to adjust the exposure states of the top surface and inside of partition walls by adding an ultraviolet absorber to the photosensitive resin composition for forming the partition walls.

Further, in such an optical element such as an organic EL element, in recent years, in order to improve the production efficiency, for example, in Patent Document 2, a negative photosensitive resin composition has been proposed whereby it is possible to selectively impart good ink repellency to the top surface of partition walls even by exposure with a low exposure amount and the ink-repellent is less likely to remain in opening sections. In Patent Document 2, the above effects have been accomplished by using a silicone compound having a mercapto group and a group having fluorine atoms as an ink-repellent in the photosensitive resin composition for forming partition walls. In Patent Document 2, it is disclosed to further add a benzophenone as a sensitizer and to incorporate an antioxidant, to the photosensitive resin composition.

However, in the production of an organic EL element, a quantum dot display, a TFT array or a thin-film solar cell, it has now been required to form a finer and highly precise pattern of a level which is difficult to achieve by the techniques described in Patent Document 1 and Patent Document 2. Therefore, for the purpose of forming partition walls to form a fine and highly precise pattern, if it is attempted to adjust the composition of the photosensitive resin composition for forming partition walls having ink repellency on the top surface, there has been a problem such that a development residue at opening sections tends to be substantial.

### PRIOR ART DOCUMENTS

### Patent Documents

Patent Document 1: JP-A-2005-166645

Patent Document 2: WO 2013/161829

### DISCLOSURE OF INVENTION

### Technical Problem

The present invention has been made to solve the above problem and has an object to provide a negative photosensitive resin composition for an organic EL device, a quantum dot display, a TFT array or the thin-film solar cell, whereby the top surface of partition walls has good ink repellency and it is possible to reduce a residue in opening sections, in order to make it possible to form a fine and highly precise pattern by the obtained partition walls.

The present invention has an object to provide a cured resin film for an organic EL device, a quantum dot display, a TFT array or a thin film solar cell, having a good ink repellency on the top surface, and partition walls for an organic EL device, a quantum dot display, a TFT array or a thin film solar cell, having a good ink repellency on the top surface, whereby it is possible to form a fine and highly precise pattern.

The present invention further has an object to provide an optical element, specifically an organic EL element, a quantum dot display, a TFT array or a thin-film solar cell, having dots formed with good precision by uniform application of ink in opening sections partitioned by partition walls.

### Solution to Problem

The present invention has subject matters of the following [1] to [11].

[1] A negative photosensitive resin composition for an organic EL element, a quantum dot display, a TFT array or a thin film solar cell, characterized by comprising an alkali-soluble resin or alkali-soluble monomer (A) having a photo-curable property, a photopolymerization initiator (B), a reactive ultraviolet absorber (C), a polymerization inhibitor (D) and an ink repellent (E).
[2] The negative photosensitive resin composition according to [1], wherein in the total solid content in the negative photosensitive resin composition, the content of the reactive ultraviolet absorber (C) is from 0.01 to 20 mass %, and the content of the polymerization inhibitor (D) is from 0.001 to 1 mass %.
[3] The negative photosensitive resin composition according to [1] or [2], wherein the reactive ultraviolet absorber (C) is a reactive ultraviolet absorber (C1) having a benzophenone skeleton, a benzotriazole skeleton, a cyano acrylate skeleton or a triazine skeleton, and having an ethylenic double bond.
[4] The negative photosensitive resin composition according to [3], wherein the reactive ultraviolet absorber (C1) is a compound represented by the following formula (C11):

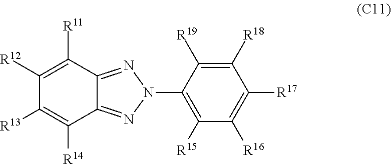

in the formula (C11), R¹¹ to R¹⁹ are each independently a hydrogen atom, a hydroxy group, a halogen atom or a monovalent substituted or unsubstituted hydrocarbon group which is bonded to the benzene ring directly or via an oxygen atom and which may have at least one member selected from an ethylenic double bond, an etheric oxygen atom and an ester bond, between carbon atoms, provided that at least one of R¹¹ to R¹⁹ has an ethylenic double bond.
[5] The negative photosensitive resin composition according to any one of [1] to [4], wherein the ink repellent (E) has fluorine atoms, and the content of fluorine atoms in the ink repellent (E) is from 1 to 40 mass %.
[6] The negative photosensitive resin composition according to any one of [1] to [5], wherein the ink repellent (E) is a compound having an ethylenic double bond.
[7] The negative photosensitive resin composition according to any one of [1] to [6], wherein the ink repellent (E) is a partially hydrolyzed condensate of a hydrolyzable silane compound.
[8] A cured resin film for an organic EL element, a quantum dot display, a TFT array or a thin film solar cell, characterized by being formed by using the negative photosensitive resin composition as defined in any one of [1] to [7].
[9] Partition walls for an organic EL element, a quantum dot display, a TFT array or a thin film solar cell, which are formed to partition a substrate surface into a plurality of compartments for forming dots, and which are characterized by being made of the cured resin film as defined in [8].
[10] An optical element having partition walls located between a plurality of dots and their adjacent dots on a substrate surface, the optical element being an organic EL element, a quantum dot display, a TFT array or a thin film solar cell, and characterized in that said partition walls are formed of the partition walls as defined in [9].
[11] The optical element according to [10], wherein the dots are formed by an inkjet method.

### Advantageous Effects of Invention

According to the present invention, it is possible to provide a negative photosensitive resin composition for an organic EL device, a quantum dot display, a TFT array or a thin film solar cell, whereby the top surface of partition walls obtainable has good ink repellency and it is possible to reduce a residue in opening sections, and thus, it is possible to form a fine and highly precise pattern by the partition walls.

The cured resin film for an organic EL device, a quantum dot display, a TFT array or a thin film solar cell, of the present invention, has good ink repellency on the top surface, and the partition walls for an organic EL device, a quantum dot display, a TFT array or a thin-film solar cell, have good ink repellency on the top surface and are capable of forming a fine and highly precise pattern.

The optical element of the present invention is an optical element, specifically an organic EL element, a quantum dot display, a TFT array or a thin-film solar cell, having a dots formed with good precision by uniform application of ink in opening sections partitioned by partition walls.

### DESCRIPTION OF EMBODIMENTS

In this specification, the following terms are used, respectively, in the following meanings.

A “(meth)acryloyl group” is a general term for a “methacryloyl group” and an “acryloyl group”. The same applies to a (meth)acryloyloxy group, (meth)acrylic acid, a (meth)acrylate, a (meth)acrylamide, and a (meth)acrylic resin.

A group represented by the formula (x) may be referred to simply as a group (x).

A compound represented by the formula (y) may be referred to simply as a compound (y). Here, the formula (x) and the formula (y) represent optional formulae.

A “resin composed mainly of a certain component” or a “resin constituted mainly by a certain component” means that the proportion of the component occupies at least 50% in the total amount of the resin.

A “side chain” is a group other than a hydrogen or halogen atom, bonded to a carbon atom constituting the main chain in a polymer wherein repeating units made of carbon atoms constitute the main chain.

The “total solid content of the photosensitive resin composition” is meant for components to form a cured film described later, among components contained in the photosensitive resin composition and is obtained from a residue remaining after heating the photosensitive resin composition at 140° C. for 24 hours to remove any solvent. Here, the total solid content can also be calculated from the charged amounts.

A film made of a cured product of a composition comprising a resin as the main component is referred to as a “cured resin film”.

A film obtained by applying a photosensitive resin composition is referred to as a “coating film”, and a film formed by drying it is referred as a “dried film”. A film obtained by curing such a “dried film” is a “cured resin film”. Further, a “cured resin film” may sometimes be referred to simply as a “cured film”.

The cured resin film may be in the form of partition walls formed in a shape to partition the predetermined region into a plurality of compartments. Into the compartments partitioned by the partition walls, i.e. opening sections surrounded by the partition walls, for example, the following “ink” is injected to form “dots”.

An “ink” is a general term for a liquid having optical and/or electrical functions after being dried, cured, etc.

In an organic EL element, a quantum dot display, a TFT array and a thin film solar cell, dots as various constituent elements may be pattern-printed by an ink-jet (IJ) method using an ink for the dot formation. The “ink” includes an ink used in such applications.

The “ink repellency” is a property to repel the ink and has both water repellency and oil repellency. The ink repellency may be evaluated, for example, by the contact angle when an ink is dropped. The “ink-philicity” is a property opposite to the ink repellency, and may be evaluated by the contact angle when an ink is dropped in the same manner as for the ink repellency. Or, the ink-philicity may be evaluated by assessing the degree of wet spreading of ink (spreadability of ink) when an ink is dropped, by predetermined standards.

A “dot” represents an optically modulatable minimum region in an optical element. In organic EL elements, quantum dot displays, TFT arrays and thin film solar cells, in the case of black and white presentation, 1 dot=1 pixel, and in the case of a colored representation, e.g. 3 dots (R (red), G (green), B (blue))=1 pixel.

A “percent (%)” represents mass % unless otherwise specified.

### (Alkali-Soluble Resin or Alkali-Soluble Monomer (A))

By putting a reference symbol (AP) to an alkali-soluble resin and a reference symbol (AM) to an alkali-soluble monomer, they will be respectively described. Hereinafter, the alkali-soluble resin or alkali-soluble monomer (A) may sometimes be referred to as the alkali-soluble resin or the like (A).

As the alkali-soluble resin (AP), a photosensitive resin having an acidic group and an ethylenic double bond in one molecule is preferred. As the alkali-soluble resin (AP) has an ethylenic double bond in the molecule, an exposed portion of the negative photosensitive resin composition will be cured by polymerization by radicals generated from the photopolymerization initiator (B).

The exposed portion thus sufficiently cured in this way will not be removed by an alkaline developing solution. Further, as the alkali-soluble resin (AP) has an acidic group in the molecule, a non-cured unexposed portion of the negative photosensitive resin composition can be selectively removed by an alkaline developing solution. As a result, the cured film can be made in the form of partition walls in a shape to partition a predetermined region into a plurality of compartments.

The alkali-soluble resin having an ethylenic double bond (AP) may, for example, be a resin (A-1) having a side chain with an acidic group and a side chain with an ethylenic double bond, a resin (A-2) having an acidic group and an ethylenic double bond introduced to an epoxy resin, etc. One of them may be used alone, or two or more of them may be used in combination.

Acidic groups which the alkali-soluble resin or the like (A) has, may, for example, be those disclosed in e.g. paragraphs [0106] and [0107] of WO 2014/046209 and in e.g. paragraphs [0065] and [0066] of WO 2014/069478.

Also with respect to the resin (A-1) and the resin (A-2), those disclosed in e.g. paragraphs [0108] to [0126] of WO 2014/046209 and in e.g. paragraphs [0067] to [0085] of WO 2014/069478 may, for example, be mentioned.

As the alkali-soluble resin (AP), it is preferred to use the resin (A-2), in that peeling of the cured film during development is prevented, and it is possible to obtain a pattern of dots with a high resolution, in that the linearity of the pattern is good when dots are linearly formed, and in that a smooth cured film surface can be easily obtained. Here, the linearity of the pattern being good, means that edges of the obtained partition walls are linear without chipping, etc.

The number of ethylenic double bonds contained in one molecule of the alkali-soluble resin (AP) is preferably, on average, at least 3, particularly preferably at least 6, most preferably from 6 to 200. When the number of ethylenic double bonds is at least the lower limit value in the above range, the alkali solubility can readily be differentiated between the exposed portion and the unexposed portion, and it becomes possible to form a fine pattern with less light exposure.

The mass average molecular weight of the alkali-soluble resin (AP) (hereinafter referred to also as Mw) is preferably from 1.5×10³ to 30×10³, particularly preferably from 2×10³ to 15×10³. Further, the number average molecular weight (hereinafter referred to also as Mn) is preferably from 500 to 20×10³, particularly preferably from 1.0×10³ to 10×10³. When Mw and Mn are at least the lower limit values in the above ranges, curing at the time of exposure will be sufficient, and when they are at most the upper limit values in the above ranges, developability will be good.

The acid value of the alkali-soluble resin (AP) is preferably from 10 to 300 mgKOH/g, particularly preferably from 30 to 150 mgKOH/g. When the acid value is within the above range, developability of the negative photosensitive composition will be good.

As the alkali-soluble monomer (AM), for example, a monomer (A-3) having an acidic group and an ethylenic double bond is preferably used. The acidic group and ethylenic double bond are the same as those of the alkali-soluble resin (AP). Also with respect to the acid value of the alkali-soluble monomer (AM), the same range as that of the alkali-soluble resin (AP) is preferred.

The monomer (A-3) may, for example, be ones disclosed in e.g. paragraph [0127] of WO 2014/046209, and in e.g. paragraph [0086] of WO 2014/069478.

As the alkali-soluble resin or alkali soluble monomer (A) contained in the negative photosensitive resin composition, one type may be used alone, or two or more types may be used in combination.

The content of the alkali-soluble resin or alkali-soluble monomer (A) in the total solid content in the negative photosensitive resin composition is preferably from 5 to 80 mass %, particularly preferably from 10 to 60 mass %. When the content is within the above range, the photo-curable property and developability of the negative photosensitive resin composition will be good.

### (Photopolymerization Initiator (B))

A photopolymerization initiator (B) is not particularly limited so long as it is a compound having a function as a photopolymerization initiator, and a compound that generates radicals by light is preferred.

The photopolymerization initiator (B) may, for example, be ones disclosed in e.g. paragraphs [0130] and [0131] of WO 2014/046209, and in e.g. paragraphs [0089] and [0090] of WO 2014/069478.

Among the photopolymerization initiators (B), benzophenones, aminobenzoic acids and aliphatic amines are preferred as they may express sensitizing effects when used together with other radical initiators. As the photopolymerization initiator (B), one type may be used alone, or two or more types may be used in combination.

The content of the photopolymerization initiator (B) in the total solid content in the negative photosensitive resin composition is preferably from 0.1 to 50 mass %, more preferably from 0.5 to 30 mass %, particularly preferably from 1 to 15 mass %. Further, to 100 mass % of the alkali-soluble resin or the like (A), it is preferably from 0.1 to 2,000 mass %, more preferably from 0.1 to 1,000 mass %. If the content of such (B) is in the above range, the photo-curable property and developability of the negative photosensitive resin composition will be good.

### (Reactive Ultraviolet Absorber (C))

As the reactive ultraviolet absorber (C), various organic compounds having reactivities, which are compounds having an absorption in an ultraviolet region of a wavelength of from 200 to 400 nm, may be used without any particular restriction. As the reactive ultraviolet absorber (C), one of these compounds may be used alone, or two or more of them may be used in combination.

The reactivity of the reactive ultraviolet absorber (C) is realized as the reactive ultraviolet absorber (C) has a functional group reactive by light, heat or the like. The reactive ultraviolet absorber (C) preferably has a functional group reactive by light. The reactive ultraviolet absorber (C) has reactivity and is thus reactive with a reactive component such as an alkali-soluble resin or alkali-soluble monomer (A) having a photo-curable property at the time when the negative-type photosensitive resin composition is cured, and will be firmly fixed to the resulting cured film or partition walls. Thus, bleeding out the reactive ultraviolet absorber (C) from the cured film or partition walls will be suppressed to a low level.

In the negative photosensitive resin composition of the present invention, the reactive ultraviolet absorber (C) will properly absorb the light irradiated during exposure, and further the after-described polymerization inhibitor (D) will control the polymerization, whereby it becomes possible to let curing of the composition proceed mildly. Thus, progress of curing at non-exposed portions is suppressed, which contributes to reduction of development residue at opening sections. Further, it is possible to obtain a pattern of dots with a high resolution, and it is possible to contribute to an improvement in the linearity of the pattern.

The reactive ultraviolet absorber (C) is preferably a reactive ultraviolet absorber (C1) having a benzophenone skeleton, a benzotriazole skeleton, a cyanoacrylate skeleton or a triazine skeleton and having an ethylenic double bond.

As such a reactive ultraviolet absorber (C1), a compound represented by the following formula (C11) may be mentioned as a compound having a benzotriazole skeleton; a compound represented by the following formula (C12) may be mentioned as a compound having a benzophenone skeleton; a compound represented by the following formula (C13) may be mentioned as a compound having a cyanoacrylate skeleton; or a compound represented by the following formula (C14) may be mentioned as a compound having a triazine skeleton.

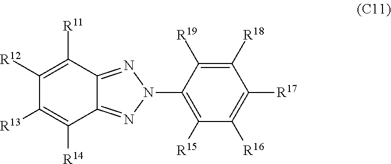

Here, in the formula (C11), R¹¹ to R¹⁹ are each independently a hydrogen atom, a hydroxy group, a halogen atom or a monovalent substituted or unsubstituted hydrocarbon group bonded directly or via an oxygen atom to the benzene ring, which may have at least one member selected from an ethylenic double bond, an etheric oxygen atom and an ester bond, between carbon atoms, provided that at least one of R¹¹ to R¹⁹ has an ethylenic double bond.

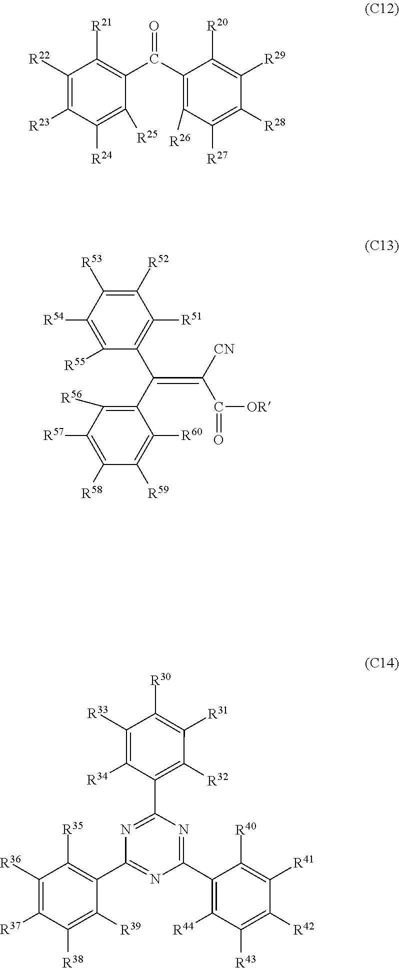

Here, in the formula (C12), each of R²⁰ to R²⁹ has the same meaning as R¹¹ to R¹⁹ in the formula (C11). Further, at least one of R²⁰ to R²⁹ has an ethylenic double bond.

In the formula (C13), R′ represents a substituted or unsubstituted monovalent hydrocarbon group, and each R⁵¹ to R⁶⁹ has the same meaning as R¹¹ to R¹⁹ in the formula (C11). Further, at least one of R⁵¹ to R⁶⁰ has an ethylenic double bond.

In the formula (C14), each of R³⁰ to R⁴⁴ has the same meaning as R¹¹ to R¹⁹ in the formula (C11). Further, at least one of R³⁰ to R⁴⁴ has an ethylenic double bond.

In the formula (C11) to the formula (C14), the number of ethylenic double bonds in a substituent represented by each of R¹¹ to R¹⁹, R²⁰ to R²⁹, R⁵¹ to R⁶⁰, R³⁰ to R⁴⁴, etc. is preferably from 1 to 6, more preferably from 1 to 3, with respect to each formula.

In the formula (C11) to the formula (C14), each of R¹¹ to R⁶⁰ in the case of a monovalent substituted or unsubstituted hydrocarbon group which has an ethylenic double bond and which may have an etheric oxygen atom, may, for example, be a C₁₋₂₀ linear or branched alkylene group, aromatic hydrocarbon group or oxyalkylene group, having a terminal (meth)acryloyloxy group.

Each of R¹¹ to R⁶⁰ in the case of a monovalent substituted or unsubstituted hydrocarbon group which has no ethylenic double bond and which may have an etheric oxygen atom, may, for example, be a C1-20 linear or branched alkyl group, aromatic hydrocarbon group or oxyalkyl group.

Among these ultraviolet absorbers (C1), the compound (C11) is preferred. As the compound (C11), a compound (C11) of the formula (C11) wherein R¹⁹ is a hydroxy group, and R¹⁶ or R¹³ is a group having a (meth)acryloyloxy group, is preferred. Here, groups other than the above in R¹¹ to R¹⁹ are each preferably a hydrogen atom, a C₁₋₄ alkyl group or a chlorine atom. When R¹⁶ is a group having a (meth)acryloyloxy group, R¹³ is preferably a hydrogen atom or a chlorine atom.

A group having a (meth)acryloyloxy group may, for example, be a (meth)acryloyloxy group, a (meth)acryloyloxyethyl group, a (meth)acryloyloxypropyl group, a (meth)acryloyloxyethoxy group, etc.

The compound (C11) may specifically be e.g. 2-(2′-hydroxy-5′-(meth)acryloyloxyethylphenyl)-2H-benzotriazole, 2-(2′-hydroxy-5′-(meth)acryloyloxyethylphenyl)-5-chloro-2H-benzotriazole, 2-(2′-hydroxy-5′-(meth)acryloyloxypropylphenyl)-2H-benzotriazole, 2-(2′-hydroxy-5′-(meth)acryloyloxypropylphenyl)-5-chloro-2H-benzotriazole, 2-(2′-hydroxy-3′-tert-butyl-5′-(meth)acryloyloxyethylphenyl)-2H-benzotriazole, 2-(2′-hydroxy-3′-tert-butyl-5′-(meth)acryloyloxyethylphenyl)-5-chloro-2H-benzotriazole, 2-(2′-hydroxy-3′-tert-butyl-5′-methylphenyl)-5 (meth)acryloyloxy-2H-benzotriazole, etc.

Among these, as the compound (C11), 2-(2′-hydroxy-5′-(meth)acryloyloxyethylphenyl)-2H-benzotriazole is preferred.

As the compound (C12), a compound (C12) of the formula (C12) wherein R²⁰ and/or R²¹ is a hydroxy group, and R²⁸ and/or R²³ is a group having a (meth)acryloyloxy group, is preferred. Groups other than the above in R²⁰ to R²⁹ are preferably hydrogen atoms. As the group having a (meth)acryloyloxy group, the same groups as in the above formula (C11) may be mentioned.

The compound (C12) may specifically be e.g. 2-hydroxy-4-(2-(meth)acryloyloxyethoxy)benzophenone, 2-hydroxy-4-(2-(meth)acryloyloxy) benzophenone, 2,2′-dihydroxy-4-(2-(meth)acryloyloxy)benzophenone, 2,2′-dihydroxy-4-(2-(meth)acryloyloxyethoxy)benzophenone, 2,2′-dihydroxy-4,4′-di(2-(meth)acryloyloxy)benzophenone, 2,2′-dihydroxy-4,4′-di(2-(meth)acryloyloxyethoxy)benzophenone, etc.

Among these, as the compound (C12), 2-hydroxy-4-(2-(meth)acryloyloxyethoxy) benzophenone is preferred.

As the compound (C13), a compound (C13) of the formula (C13) wherein R′ is an alkyl group, and R⁵³ and/or R⁵⁸ is a group having a (meth)acryloyloxy group, is preferred. Groups other than the above in R⁵¹ to R⁶⁰ are preferably hydrogen atoms. As the group having a (meth)acryloyloxy group, the same groups as in the above formula (C11) may be mentioned.

The compound (C13) may specifically be e.g. ethyl-2-cyano-3,3-di[4-(2-(meth)acryloyloxyethylphenyl)] acrylate, propyl 2-cyano-3,3-di[4-(2-(meth)acryloyloxyethoxyphenyl)], methyl 2-cyano-3,3-di[4-(2-(meth)acryloyloxyphenyl)], etc.

Among these, as the compound (C13), ethyl-2-cyano-3,3-di[4-(2-(meth)acryloyloxyethylphenyl)] acrylate is preferred.

As the compound (C14), a compound (C14) of the formula (C14) wherein at least one of the three phenyl groups attached to the triazine skeleton, is a phenyl group having a hydroxyl group at the 2-position, and having a group with a (meta)acryloyloxy group at the 4-position, is preferred. Here, the remaining groups bonded to the phenyl group are preferably hydrogen atoms. As the group having a (meth)acryloyloxy group, the same groups as in the above formula (C11) may be mentioned.

The compound (C14) may specifically be e.g. 2,4-diphenyl-6-[2-hydroxy-4-(2-(meth)acryloyloxyphenyl)]-1,3,5-triazine, 2,4-diphenyl-6-[2-hydroxy-4-(2-(meth)acryloyloxyethoxyphenyl)]-1,3,5-triazine, 2,4,6-tri[2-hydroxy-4-(2-(meth)acryloyloxyphenyl)]-1,3,5-triazine, 2,4,6-tri[2-hydroxy-4-(2-(meth)acryloyloxyethoxyphenyl)]-1,3,5-triazine, etc.

Among these, as the compound (C14), 2,4-diphenyl-6-[2-hydroxy-4-(2-(meth)acryloyloxyethoxyphenyl)]-1,3,5-triazine is preferred.

The content of the reactive ultraviolet absorber (C) in the total solid content in the negative photosensitive resin composition is preferably from 0.01 to 20 mass %, more preferably from 0.1 to 15 mass %, particularly preferably from 0.5 to 10 mass %. Further, to 100 mass % of the alkali-soluble resin or the like (A), it is preferably from 0.01 to 1,000 mass %, more preferably from 0.01 to 400 mass %. When the content of such (C) is in the above range, development residue of the negative type photosensitive resin composition will be reduced, and the pattern linearity will be good.

### (Polymerization Inhibitor (D))

The polymerization inhibitor (D) is not particularly limited so long as it is a compound having a function as a polymerization inhibitor, and preferred is a compound that well absorbs light energy and generates radicals to inhibit the reaction of the alkali-soluble resin or the like (A). In the negative photosensitive resin composition of the present invention, the above reactive ultraviolet absorber (C) properly absorbs the light irradiated during exposure, and further, the polymerization inhibitor (D) controls the polymerization, whereby it becomes possible to let curing of the composition proceed mildly. Thus, progress of curing at non-exposed portions will be suppressed, which will contribute to reduction in development residue at opening sections. Further, it is possible to obtain a pattern of dots with a high resolution, and it is possible to contribute to improvement of the linearity of the pattern.

Specifically as the polymerization inhibitor (D), it is possible to use polymerization inhibitors for common reactions, such as diphenyl picryl hydrazide, tri-p-nitrophenyl methyl, p-benzoquinone, p-tert-butylcatechol, picric acid, copper chloride, methyl hydroquinone, 4-methoxyphenol, tert-butyl hydroquinone, 2,6-di-tert-butyl-p-cresol, etc. Among them, 2-methyl hydroquinone, 2,6-di-tert-butyl-p-cresol, 4-methoxyphenol, etc. are preferred. Further, from the viewpoint of storage stability, a hydroquinone-type polymerization inhibitor is preferred, and it is particularly preferred to use 2-methyl hydroquinone.

The content of the polymerization inhibitor (D) in the total solid content in the negative photosensitive resin composition is preferably from 0.001 to 1 mass %, more preferably from 0.005 to 0.5 mass %, particularly preferably from 0.01 to 0.2 mass %. Further, to 100 mass % of the alkali-soluble resin or the like (A), it is preferably from 0.001 to 100 mass %, more preferably from 0.001 to 20 mass %. When the content of such (D) is in the above range, development residue of the negative photosensitive resin composition will be reduced, and the pattern linearity will be good.

### (Ink Repellent (E))

The ink repellent (E) has ink repellency and a property to migrate to the top surface (top surface migration property) in the process for forming a cured film using the negative photosensitive resin composition containing it. By the use of the ink repellent (E), an upper portion including the top surface of the obtainable cured film becomes to be a layer wherein the ink repellent (E) is densely present (hereinafter referred to also as “ink-repellent layer”), whereby ink repellency is imparted to the top surface of the cured film.

The ink repellent (E) having the above properties, preferably has fluorine atoms from the viewpoint of the top surface migration property and ink repellency, and in such a case, the content of fluorine atoms in the ink repellent (E) is preferably from 1 to 40 mass %, more preferably from 5 to 35 mass %, particularly preferably from 10 to 30 mass %. When the content of fluorine atoms in the ink repellent (E) is at least the lower limit value in the above range, good ink repellency can be imparted to the top surface of the cured film, and when it is at most the upper limit value, compatibility with other components in the negative photosensitive resin composition will be good.

Further, the ink repellent (E) is preferably a compound having an ethylenic double bond. When the ink repellent (E) has an ethylenic double bond, radicals will act on the ethylenic double bond of the ink repellent (E) migrated to the top surface, to facilitate cross-linking by (co-)polymerization of the ink repellent (E) one another or between the ink repellent (E) and another component having an ethylenic double bond contained in the negative photosensitive resin composition. Here, such a reaction may be accelerated by a thiol compound (G) which may optionally be contained.

Thus, in the production of a cured film obtained by curing the negative photosensitive resin composition, it is possible to improve the fixability of the ink repellent (E) in the upper layer portion of the cured film i.e. in the ink repellent layer. In the negative photosensitive resin composition of the present invention, especially in a case where a thiol compound (G) is contained, the ink repellent (E) can be sufficiently fixed in the ink repellent layer, even if the exposure amount is low during the exposure. The case where the ink repellent (E) has an ethylenic double bond, is as described above. In a case where the ink repellent (E) does not have an ethylenic double bond, the ink repellent (E) can be sufficiently fixed by sufficiently carrying out curing of photocurable components composed mainly of the alkali-soluble resin or the like (A), which are present around the ink repellent (E).

Usually, in a case where an ethylenic double bond undergoes radical polymerization, the surface in contact with the atmospheric air, of the cured film or the partition walls, is more susceptible to reaction inhibition by oxygen, but the radical reaction by the thiol compound (G) is scarcely susceptible to inhibition by oxygen and thus is particularly advantageous in fixing the ink repellent (E) at a low exposure amount. Further, in the production of partition walls, at the time of carrying out the development, it is possible to sufficiently prevent the ink repellent (E) from detaching from the ink repellent layer, or to sufficiently prevent peeling of the top surface of the ink repellent layer.

The ink repellent (E) may, for example, be a partially hydrolyzed condensate of a hydrolyzable silane compound. As the hydrolyzable silane compound, one type may be used alone, or two or more types may be used in combination. Specifically, the following ink repellent (E1) may be mentioned as an ink repellent (E) comprising a partially hydrolyzed condensate of a hydrolyzable silane compound, and having fluorine atoms. As an ink repellent (E) having fluorine atoms, an ink repellent (E2) may be used which comprises a compound having a hydrocarbon chain as the main chain and containing fluorine atoms in its side chain.

The ink repellent (E1) and the ink repellent (E2) may be used alone or in combination. In the present invention, it is particularly preferred to use the ink repellent (E1) from the viewpoint of excellent ultraviolet/ozone resistance.

The ink repellent (E1) is a partially hydrolyzed condensate of a hydrolyzable silane compound mixture (hereinafter referred to also as “mixture (M)”). The mixture (M) contains a hydrolyzable silane compound having a fluoroalkylene group and/or fluoroalkyl group and a hydrolyzable group (hereinafter referred to also as “hydrolyzable silane compound (s1)”) as an essential component and optionally contains any hydrolyzable silane compounds other than the hydrolyzable silane compound (s1). As the hydrolyzable silane compounds to be optionally contained in the mixture (M), the following hydrolyzable silane compounds (s2) to (s4) may be mentioned. The hydrolyzable silane compound (s2) is particularly preferred as a hydrolyzable silane compound to be optionally contained in the mixture (M).

Hydrolyzable silane compound (s2): a hydrolyzable silane compound having four hydrolyzable groups bonded to a silicon atom.

Hydrolyzable silane compound (s3): a hydrolyzable silane compound having a group with an ethylenic double bond and a hydrolyzable group and containing no fluorine atom.

Hydrolyzable silane compound (s4): a hydrolyzable silane compound having only a hydrocarbon group and a hydrolyzable group as groups bonded to a silicon atom.

The mixture (M) may further optionally contain one or more hydrolyzable silane compounds other than the hydrolyzable silane compounds (s1) to (s4). As such other hydrolyzable silane compounds, a hydrolyzable silane compound having a mercapto group and a hydrolyzable group and containing no fluorine atom, a hydrolyzable silane compound having an epoxy group and a hydrolyzable group and containing no fluorine atom, a hydrolyzable silane compound having an oxyalkylene group and a hydrolyzable group and containing no fluorine atom, etc. may be mentioned.

As the hydrolyzable silane compounds (s1) to (s4) and other hydrolyzable silane compounds, those disclosed in e.g. paragraphs [0033] to [0072] of WO 2014/046209, and in e.g. paragraphs [0095] to [0136] of WO 2014/069478, may, for example, be mentioned.

The ink repellent (E1) can be prepared from the mixture (M) containing the above hydrolyzable silane compounds by methods described in e.g. paragraphs [0073] to [0078] of WO 2014/046209, and in e.g. paragraphs [0137] to [0143] of WO 2014/069478. At that time, the molar ratios of the respective hydrolyzable silane compounds in the mixture (M) may suitably be set so that, in the obtainable ink repellent (E1), the content of fluorine atoms would be within the above-mentioned preferred range, and the effects of the above respective hydrolyzable silane compounds would be well balanced.

Specifically, in a case where the hydrolyzable silane compounds (s1) to (s4) are combined for use, the molar ratios of the respective components can be set as follows when the entirety is taken as 1.

The hydrolyzable silane compound (s1) is preferably from 0.02 to 0.4, and the hydrolyzable silane compound (s2) is preferably from 0 to 0.98, particularly preferably from 0.05 to 0.6. The hydrolyzable silane compound (s3) is preferably from 0 to 0.8, particularly preferably from 0.2 to 0.5. The hydrolyzable silane compound (s4) is preferably from 0 to 0.5, particularly preferably from 0.05 to 0.3.

As the ink repellent (E2), specifically, those disclosed in e.g. paragraphs [0079] to [0102] of WO 2014/046209, and in e.g. paragraphs [0144] to [0170] of WO 2014/069478, may be mentioned.

The content of the ink repellent (E) in the total solid content in the negative photosensitive resin composition is preferably 0.01 to 15 mass %, more preferably from 0.01 to 5 mass %, particularly preferably from 0.03 to 1.5 mass %. Further, to 100 mass % of the alkali-soluble resin or the like (A), it is preferably from 0.01 to 500 mass %, more preferably from 0.01 to 300 mass %. When the content of such (E) is at least the lower limit value in the above range, the top surface of a cured film to be formed from the negative photosensitive resin composition will have excellent ink repellency. When it is at most the upper limit value in the above range, the adhesion between the cured film and the substrate will be good.

### (Crosslinking Agent (F))

The crosslinking agent (F) which may be optionally contained in the negative photosensitive resin composition, is a compound having at least two ethylenic double bonds in one molecule and having no acidic group. By containing the crosslinking agent (F), curability of the negative photosensitive resin composition at the time of exposure, will be improved, and it will be possible to form a cured film with a lower exposure amount.

As the crosslinking agent (F), diethylene glycol di(meth)acrylate, trimethylolpropane tri(meth)acrylate, pentaerythritol (meth)acrylate, dipentaerythritol (meth)acrylate, tripentaerythritol (meth)acrylate, tetrapentaerythritol (meth)acrylate, pentaerythritol tri(meth)acrylate, pentaerythritol tetra(meth)acrylate, ditrimethylolpropane tetra(meth)acrylate, dipentaerythritol penta(meth)acrylate, dipentaerythritol hexa(meth)acrylate, ethoxylated isocyanuric acid tri(meth)acrylate, tris-(2-acryloyloxyethyl) isocyanurate, ε-caprolactone-modified tris-(2-acryloyloxyethyl) isocyanurate, urethane acrylate, etc. may be mentioned.

From the viewpoint of the optical reactivity, it is preferred to have many ethylenic double bonds. For example, pentaerythritol tetra(meth)acrylate, ditrimethylolpropane tetra(meth)acrylate, dipentaerythritol hexa(meth)acrylate, dipentaerythritol penta(meth)acrylate, ethoxylated isocyanuric acid tri(meth)acrylate, urethane acrylate, etc. are preferred. As the crosslinking agent (F), one type may be used alone, or two or more types may be used in combination.

The content of the crosslinking agent (F) in the total solid content of the negative photosensitive resin composition is preferably from 10 to 60 mass %, particularly preferably from 20 to 55 mass %. Further, to 100 mass % of the alkali-soluble resin or the like (A), it is preferably from 0.1 to 1200 mass %, more preferably from 0.2 to 1100 mass %.

### (Thiol Compound (G))

The thiol compound (G) which may be optionally contained in the negative photosensitive resin composition, is a compound having at least two mercapto groups in one molecule. If the thiol compound (G) is contained, at the time of exposure, radicals of the thiol compound (G) will be formed by radicals formed by the photo-polymerization initiator (B) and will act on ethylenic double bonds in the alkali-soluble resin or the like (A) or in other components contained in the negative photosensitive resin composition, thereby to cause a so-called ene-thiol reaction. This ene-thiol reaction is, as different from usual radical polymerization of ethylenic double bonds, not susceptible to reaction inhibition by oxygen, and thus, has a high chain transfer property and further carries out cross-linking at the same time as polymerization, whereby there will be advantages such that shrinkage will be low when formed into a cured product, and a uniform network will be readily obtainable.

In a case where the negative photosensitive resin composition contains a thiol compound (G), as mentioned above, curing can be sufficiently done even at a low exposure amount, and particularly even at the upper layer portion including the top surface of partition walls susceptible to reaction inhibition by oxygen, photocuring will be sufficiently performed, and it becomes possible to impart good ink repellency to the top surface of the partition walls.

The number of mercapto groups contained in the thiol compound (G) is preferably from 2 to 10, more preferably from 2 to 8, further preferably from 2 to 5, per molecule. From the viewpoint of storage stability of the negative photosensitive resin composition, it is particularly preferably 3.

The molecular weight of the thiol compound (G) is not particularly limited. The mercapto group equivalent (hereinafter referred to also as “SH equivalent”) represented by [molecular weight/number of mercapto groups] in the thiol compound (G), is preferably from 40 to 1,000, more preferably from 40 to 500, particularly preferably from 40 to 250, from the viewpoint of curability at a low exposure amount.

The thiol compound (G) may specifically be e.g. tris(2-mercaptopropanoyloxyethyl) isocyanurate, pentaerythritol tetrakis(3-mercaptobutyrate), trimethylolpropane tristhioglycolate, pentaerythritol tristhioglycolate, pentaerythritol tetrakisthioglycolate, dipentaerythritol hexathioglycolate, trimethylolpropane tris(3-mercaptopropionate), pentaerythritol tetrakis(3-mercaptopropionate), tris-[(3-mercaptopropionyloxy)-ethyl]-isocyanurate, dipentaerythritol hexa(3-mercaptopropionate), trimethylolpropane tris(3-mercapto butyrate), pentaerythritol tetrakis(3-mercapto butyrate), dipentaerythritol hexa(3-mercapto butyrate), trimethylolpropane tris(2-mercapto isobutyrate), 1,3,5-tris(3-mercaptobutyryloxyethyl)-1,3,5-triazine-2,4,6(1H, 3H, 5H)-trione, triphenolmethane tris(3-mercaptopropionate), triphenolmethane tris(3-mercaptobutyrate), trimethylolethane tris(3-mercaptobutyrate), 2,4,6-trimercapto-S-triazine, etc. As the thiol compound (G), one type may be used alone, or two or more types may be used in combination.

In a case where the negative photosensitive resin composition contains the thiol compound (G), its content is such that mercapto groups per 1 mol of ethylenic double bonds in the total solid content of the negative photosensitive resin composition would be in an amount of preferably from 0.0001 to 1 mol, more preferably from 0.0005 to 0.5 mol, particularly preferably from 0.001 to 0.5 mol. Further, to 100 mass % of the alkali-soluble resin or the like (A), it is preferably from 0.1 to 1200 mass %, more preferably from 0.2 to 1,000 mass %. If the content of such (G) is within the above range, the photo-curable property and developability of the negative photosensitive resin composition will be good even at a low exposure amount.

### (Phosphoric Acid Compound (H))

The negative photosensitive resin composition of the present invention may contain a phosphoric acid compound (H) in order to improve the adhesion of the obtainable cured film to a substrate or transparent electrode material such as ITO.

The phosphoric acid compound (H) is not particularly limited so long as it is one capable of improving the adhesion to the substrate or transparent electrode material, but is preferably a phosphoric acid compound having an ethylenic unsaturated double bond in its molecule.

The phosphoric acid compound having an ethylenic unsaturated double bond in its molecule, is preferably a phosphoric acid (meth) acrylate compound, i.e. a compound having at least a O═P structure derived from phosphoric acid and a (meth)acryloyl group being an ethylenic unsaturated double bond derived from a (meth) acrylic acid compound, in its molecule, or a vinyl phosphate compound.

The phosphoric acid (meth)acrylate compound may, for example, be mono(2-(meth)acryloyloxyethyl) acid phosphate, di(2-(meth)acryloyloxyethyl) acid phosphate, di(2-acryloyloxyethyl) acid phosphate, tris((meth)acryloyloxyethyl) acid phosphate, mono(2-methacryloyloxyethyl) caproate acid phosphate, etc.

Further, as the phosphoric acid compound (H), other than a phosphoric acid compound having an ethylenic unsaturated double bond in the molecule, phenylphosphonic acid or the like may be used.

As the phosphoric acid compound (H), one of the compounds classified into this may be used alone, or two or more of them may be used in combination.

In a case where a phosphoric acid compound (H) is contained, its content in the total solid content of the negative photosensitive resin composition is preferably from 0.01 to 10 mass %, particularly preferably from 0.1 to 5 mass %. Further, to 100 mass % of the alkali-soluble resin or the like (A), it is preferably from 0.01 to 200 mass %, more preferably from 0.1 to 100 mass %. When the content of such (H) is within the above range, the adhesion between the obtainable cured film and the substrate or the like will be good.

### (Coloring Agent (I))

The negative photosensitive resin composition may contain a coloring agent (I), depending on the application, in the case of imparting a light-shielding property to a cured film, especially to partition walls. As the coloring agent (I), various inorganic pigments or organic pigments may be mentioned, such as carbon black, aniline black, anthraquinone black pigment, perylene black pigment, azomethine black pigment, etc.

As the coloring agent (I), a mixture of organic pigments and/or inorganic pigments, such as red pigment, blue pigment and green pigment, may also be used.

Specific examples of preferred organic pigments include 2-hydroxy-4-n-octoxybenzophenone, methyl-2-cyanoacrylate, 2,4-bis[2-hydroxy-4-butoxyphenyl]-6-(2,4-dibutoxyphenyl)-1,3,5-triazine, C. I. Pigment Black 1, 6, 7, 12, 20, 31, C. I. Pigment Blue 15:6, Pigment Red 254, Pigment Green 36, Pigment Yellow 150, etc.

As the coloring agent (I), one type may be used alone, or two or more types may be used in combination. In a case where the coloring agent (I) is to be contained, the content of the coloring agent (I) in the total solid content is preferably from 15 to 65 mass %, particularly preferably from 20 to 50 mass %. Further, to 100 mass % of the alkali-soluble resin or the like (A), it is preferably from 15 to 1,500 mass %, more preferably from 20 to 1,000 mass %. When the content of such (I) is within the above range, the obtainable negative photosensitive resin composition will be good in the sensitivity, and the partition walls to be formed will be excellent in the light-shielding property.

### (Solvent (J))

When the negative photosensitive resin composition contains a solvent (J), its viscosity is reduced, and it becomes easy to apply the negative photosensitive resin composition to the substrate surface. As a result, a coating film of the negative photosensitive resin composition having a uniform thickness can be formed.

As the solvent (J), known solvents may be used. As the solvent (J), one type may be used alone, or two or more types may be used in combination.

The solvent (J) may, for example, be alkylene glycol alkyl ethers, alkylene glycol alkyl ether acetates, alcohols, solvent naphthas, etc. Among them, at least one solvent selected from the group consisting of alkylene glycol alkyl ethers, alkylene glycol alkyl ether acetates and alcohols, is preferred, and at least one solvent selected from the group consisting of propylene glycol monomethyl ether acetate, propylene glycol monomethyl ether, diethylene glycol ethyl methyl ether, diethylene glycol monoethyl ether acetate and 2-propanol, is more preferred.

The content of the solvent (J) in the negative photosensitive resin composition is preferably 50 to 99 mass %, more preferably from 60 to 95 mass %, particularly preferably from 65 to 90 mass %, to the total amount of the composition. Further, to 100 mass % of the alkali-soluble resin or the like (A), it is preferably from 0.1 to 3,000 mass %, more preferably from 0.5 to 2,000 mass %.

### (Other Components)

The negative photosensitive resin composition may further contain, as the case requires, one or more of other additives, such as a thermal crosslinking agent, a polymer dispersing agent, a dispersing aid, a silane coupling agent, fine particles, a curing accelerator, a thickener, a plasticizer, a defoaming agent, a leveling agent and a cissing agent.

The negative photosensitive resin composition of the present invention is obtainable by mixing predetermined amounts of the above respective components. The negative photosensitive resin composition of the present invention is for an organic EL element, for a quantum dot display, for a TFT array or for a thin-film solar cell, and can exhibit its effectiveness particularly when used for the formation of, for example, a cured film or partition walls to be used for an organic EL element, a quantum dot display, a TFT array or a thin film solar cell. By using the negative photosensitive resin composition of the present invention, it is possible to produce a cured film, particularly partition walls, having good ink repellency on the top surface. Further, most of the ink repellent (E) is sufficiently fixed in the ink-repellent layer, and the ink repellent (E) which is present at a low concentration in the partition wall portion below the ink-repellent layer, is also fixed as the partition walls are sufficiently photo-cured, so that during development, the ink repellent (E) is less likely to migrate into opening sections surrounded by the partition walls, and thus, it is possible to obtain opening sections in which ink can be uniformly applied.

Further, in the negative photosensitive resin composition, the reactive ultraviolet absorber (C) properly absorbs light irradiated during exposure, and further, the polymerization inhibitor (D) controls the polymerization, whereby it becomes possible to let curing of the composition proceed mildly. Thus, progress of curing at non-exposed portions is suppressed, which can contribute to reduction in development residue at opening sections. Further, it is possible to obtain a pattern of dots with a high resolution, and it is possible to contribute to improvement of the linearity of the pattern.

Further, at the time when the negative photosensitive resin composition is cured, the reactive ultraviolet absorber (C) reacts with reactive components of e.g. the photocurable alkali-soluble resin or alkali-soluble monomer (A) and will be firmly fixed to the obtainable cured film or partition walls. Thus, bleeding out of the reactive ultraviolet-absorber (C) from the cured film or partition walls can be suppressed to a low level, and the generation amount of outgassing will be reduced.

### [Cured Resin Film and Partition Walls]

The cured resin film of the present invention is formed by using the negative photosensitive resin composition of the present invention. A cured resin film in an embodiment of the present invention is obtained, for example, by applying the negative photosensitive resin composition of the present invention to the surface of a substrate such as a base plate, and, if necessary, drying to remove a solvent, followed by exposure for curing. The cured resin film of the present invention presents particularly remarkable effects, when it is used for an optical element, in particular, for an organic EL element, a quantum dot display, a TFT array or a thin-film solar cell.

The partition walls of the present invention are partition walls made of the above cured film of the present invention, which are formed in the shape to partition a substrate surface into a plurality of compartments for forming dots. The partition walls are obtainable, for example, in the above-described preparation of the cured resin film, by masking portions to become compartments for forming dots, before exposure, followed by exposure and then by development. By the development, non-exposed portions by masking will be removed, whereby opening sections corresponding to the compartments for forming dots, will be formed together with the partition walls. The partition walls exhibit particularly remarkable effects when they are used for an optical element, in particular, for an organic EL element, a quantum dot display, a TFT array or a thin-film solar cell.

The partition walls of the present invention can be produced, for example, by the methods disclosed in e.g. paragraphs [0142] to [0152] of WO 2014/046209 and in e.g. paragraphs [0206] to [0216] of WO 2014/069478.

In the partition walls of the present invention, for example, the width is preferably at most 100 μm, particularly preferably at most 20 μm. Further, the distance between adjacent partition walls (the width of pattern) is preferably at most 300 μm, particularly preferably at most 100 μm. The height of the partition walls is preferably from 0.05 to 50 μm, particularly preferably form 0.2 to 10 μm.

The partition walls of the present invention are excellent in linearity with little unevenness at edge portions thereof when they are formed to have the above width. Here, development of the high linearity in the partition walls is particularly remarkable in a case where a resin (A-2) having an acid group and an ethylenic double bond introduced into an epoxy resin is used as the alkali-soluble resin. Thus, it becomes possible to form a pattern with a high precision even in the case of a fine pattern. With such a high precision pattern formation, the partition walls will be particularly useful as partition walls for organic EL elements.

At the time of carrying out pattern printing by IJ method, the partition walls of the present invention can be used as partition walls to define opening sections to be ink injection regions. At the time of carrying out pattern printing by IJ method, if the partition walls are used in such a form that the opening sections would coincide with the desired ink injection regions, since the top surface of the partition walls has good ink repellency, it is possible to prevent the ink from being injected beyond the partition walls into undesired opening sections i.e. ink injection regions. Further, in the opening sections surrounded by the partition walls, the wet-spreadability of ink is good, whereby it becomes possible to print ink uniformly in the desired regions without bringing about e.g. white spots or the like.

By using the partition walls of the present invention, it is possible to precisely carry out the pattern printing by IJ method as described above. Thus, the partition walls of the present invention are useful as partition walls for an optical element having partition walls located between a plurality of dots and their adjacent dots on the surface of a substrate having the dots formed by IJ method, in particular, for an organic EL element, a quantum dot display, a TFT array or a thin film solar cell.

### [Optical Element]

The organic EL element, the quantum dot display, the TFT array or the thin film solar cell, as an optical element of the present invention, is an organic EL element, a quantum dot display, a TFT array or a thin-film solar cell, having the above-described partition walls of the present invention located between a plurality of dots and their adjacent dots on the substrate surface. In the optical element of the present invention, the dots are preferably formed by IJ method.

The organic EL element has a structure wherein a luminescent layer of an organic thin film is sandwiched between an anode and a cathode, and the partition walls of the present invention can be used for applications as partition walls to partition the organic luminescent layer, as partition walls to partition an organic TFT layer, as partition walls to partition a coated type oxide semiconductor, etc.

Further, the organic TFT array element is an element wherein a plurality of dots are arranged in a plan view matrix; for each dot, pixel electrodes and TFT as a switching element for driving the pixel electrodes are provided; and an organic semiconductor layer is used as a semiconductor layer including a channel layer of TFT. Such an organic TFT array element is provided as a TFT array substrate, for example, in an organic EL element or a liquid crystal element.

The optical element in the embodiment of the invention can be prepared by the methods disclosed in e.g. paragraph [0153] of WO 2014/046209 and in e.g. paragraphs [0220] to [0223] of WO 2014/069478.

In the optical element of the present invention, by using the partition walls of the present invention, it is possible to let ink wet-spread uniformly without irregularities in opening sections partitioned by the partition walls in the production process, whereby an optical element having dots formed with a high precision is obtainable.

Here, the organic EL element maybe produced, for example, in the following manner, but the method is not limited to this.

A transparent electrode of e.g. a light-transmissive tin-doped indium oxide (ITO) is formed by sputtering or the like on a transparent substrate of e.g. glass. This transparent electrode may be patterned as the case requires.

Then, using the negative photosensitive resin composition of the present invention, partition walls are formed in a grid-pattern in a plan view along the contour of each dot, by a photolithography method including coating, exposure and development.

Then, in each dot, by IJ method, materials for a hole injection layer, a hole transport layer, a luminescent layer, a hole blocking layer and an electron injection layer are, respectively, applied and dried to sequentially laminate these layers. The types and number of organic layers to be formed in the dot are suitably designed. Finally, a reflective electrode of e.g. aluminum, or a transparent electrode of e.g. ITO, is formed by e.g. a vapor deposition method.

Whereas, the quantum dot display may be formed, for example, as follows. A translucent electrode of e.g. tin-doped indium oxide (ITO) is formed by e.g. a sputtering method on a transparent substrate of e.g. glass. This transparent electrode may be patterned as the case requires.

Then, using the negative photosensitive resin composition of the present invention, partition walls are formed in a grid-pattern in a plan view along the contour of each dot, by a photolithography method including coating, exposure and development.

Then, in a dot, by IJ method, materials for a hole injection layer, a hole transport layer, a quantum dot layer, a hole blocking layer and an electron injection layer are, respectively, applied and dried to sequentially laminate these layers. The types and number of organic layers to be formed in the dot are suitably designed. Finally, a reflective electrode of e.g. aluminum, or a transparent electrode of e.g. ITO is formed by e.g. a vapor deposition method.

Further, the optical element of the present invention is applicable also to a blue light conversion type quantum dot display, which is prepared, for example, as follows.

Using the negative photosensitive resin composition of the present invention, partition walls are formed in a grid-pattern in a plan view along the contour of each dot, on a transparent substrate of e.g. glass.

Then, in each dot, by IJ method, a nanoparticle solution to convert blue light to green light, a nanoparticle solution to convert blue light to red light, and, as the case requires, a blue color ink, are applied and dried to prepare a module. By using a blue color-emitting light source as a backlight and the above module as a substitute for the color filter, it is possible to obtain a liquid crystal display excellent in color reproducibility.

The TFT array can be produced as follows, but the method is not limited thereto.

A gate electrode of e.g. aluminum or its alloy is formed by e.g. a sputtering method on a transparent substrate of e.g. glass. This gate electrode may be patterned as the case requires.

Then, a gate insulating film of e.g. silicon nitride is formed by e.g. a plasma CVD method. A source electrode and a drain electrode may be formed on the gate insulating film. The source electrode and the drain electrode may be prepared, for example, by forming a metal thin film of e.g. aluminum, gold, silver, copper or an alloy thereof, by vacuum vapor deposition or sputtering. As a method of patterning the source electrode and the drain electrode, a technique may, for example, be mentioned wherein after forming the metal thin film, a resist is applied, exposed and developed to let the resist remain at portions desired to form electrodes, then the exposed metal is removed by e.g. phosphoric acid or aqua regia, and finally removing the resist. Further, in a case where a thin metal film of e.g. gold is to be formed, there may be a technique wherein a resist is preliminarily applied, exposed and developed to let the resist remain at portions not desired to form electrodes, then after forming the metal thin film, the photoresist is removed together with the metal thin film. Otherwise, a source electrode and a drain electrode may be formed by a technique of e.g. ink-jet using a metal nano-colloid of e.g. silver or copper.

Then, using the negative photosensitive resin composition of the present invention, partition walls are formed in a grid-pattern in a plan view, by a photolithography method including coating, exposure and development.

Then, a semiconductor solution is applied into dots by IJ method, followed by drying the solution to form a semiconductor layer. As such a semiconductor solution, an organic semiconductor solution, or an inorganic coating-type oxide semiconductor solution may also be used. A source electrode and a drain electrode may be formed after forming this semiconductor layer by a technique of e.g. ink-jet.

Finally, a translucent electrode of e.g. ITO is formed by e.g. a sputtering method, and a protective film of e.g. silicon nitride is formed by deposition.

### EXAMPLES

Now, the present invention will be described in further detail with reference to the following Examples, but the present invention is not limited to these Examples. Here, Ex. 1 to 15 are Examples of the present invention, and Ex. 16 to 18 are Comparative Examples.

The respective measurements were conducted by the following methods.

### [Number Average Molecular Weight (Mn) and Mass Average Molecular Weight (Mw)]

Gel permeation chromatography (GPC) of a plurality of monodisperse polystyrene polymers different in degree of polymerization, which are commercially available as standard samples for molecular weight measurements, was measured by means of a commercially available GPC measuring device (manufactured by TOSOH Corp., device name: HLC-8320GPC). A calibration curve was prepared based on the relationship between the molecular weight of polystyrene and the holding time (retention time).

Each sample was diluted to 1.0 mass % with tetrahydrofuran, and after being passed through a 0.5 μm filter, GPC was measured by using the above apparatus. Using the above calibration curve, the GPC spectrum was analyzed by a computer analysis to obtain Mn and Mw of the sample.

### [PGMEA Contact Angle]

By a sessile drop method, in accordance with JIS R3257 “Wettability test method of substrate glass surface”, PGMEA droplets were placed at three locations on the measuring surface of the substrate, and each PGMEA droplet was measured. The droplets were 2 μL/droplet, and the measurement was conducted at 20° C. The contact angle was obtained as an average value of 3 measured values (n=3). Here, PGMEA is the abbreviation of propylene glycol monomethyl ether acetate.

Abbreviations of compounds used in the respective Examples are as follows.

### (Alkali-Soluble Resin (A))

A-21: A resin having a solid content of 70 mass % and an acid value of 60 mgKOH/g, obtained by reacting a cresol novolak epoxy resin with acrylic acid and then with 1,2,3,6-tetrahydro phthalic anhydride to obtain a resin having an acryloyl group and a carboxyl group introduced and purifying such a resin with hexane.

A-22: A resin having a solid content of 70 mass % and an acid value of 60 mgKOH/g, obtained by introducing a carboxyl group and an ethylenic double bond to a bisphenol A type epoxy resin.

A-23: A resin having an ethylenic double bond and an acidic group introduced to an epoxy resin having a biphenyl skeleton, represented by the formula (A-2a) (solid content: 70 mass %, PGMEA: 30 mass %, Mw=4000, acid value: 70 mgKOH/g).

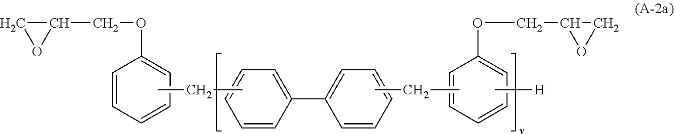

(In the formula (A-2a), v is a number satisfying the above Mw.)

A-24: A resin having an ethylenic double bond and an acidic group introduced to an epoxy resin represented by the formula (A-2b) (solid content: 70 mass %, PGMEA: 30 mass %, Mw=3000, acid value: 50 mgKOH/g).

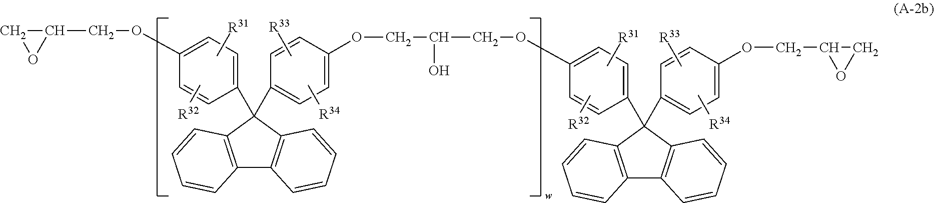

(In the formula (A-2b), R³¹, R³², R³³ and R³⁴ are hydrogen atoms, and w is a number satisfying the above Mw.)

### (Photopolymerization Initiator (B))

IR907: trade name: IRGACURE907, manufactured by BASF Corp., 2-methyl-1-[4-(methylthio)phenyl]-2-morpholinopropan-1-one.

IR369: trade name: IRGACURE369, manufactured by BASF Corp., 2-benzyl-2-dimethylamino-1-(4-morpholinophenyl)-butan-1-one.

OXE01: trade name: OXE01, manufactured by BASF Corp., 1,2-octanedione, 1-[4-(phenylthio)-, 2-(O-benzoyloxime).

OXE02: trade name: OXE02, manufactured by Ciba Specialty Chemicals, ethanone 1-[9-ethyl-6-(2-methylbenzoyl)-9H-carbazol-3-yl]-1-(0-acetyloxime).

### (Photo-Polymerization Initiator (B); Non-Reactive Ultraviolet Absorber (Sensitizer))

EAB: 4,4′-bis(diethylamino)benzophenone.

Tinuvin 329: manufactured by BASF Corp., 2-(2H-benzotriazol-2-yl)-4-(1,1,3,3-tetramethylbutyl) phenol.

### (Reactive Ultraviolet Absorber (C))

C-1: 2-(2′-hydroxy-5′-methacryloyloxyethylphenyl)-2H-benzotriazole.

### (Polymerization Inhibitor (D))

BHT: 2,6-di-tert-butyl-p-cresol

MHQ: 2-methylhydroquinone

MEHQ: 4-methoxyphenol

### (Hydrolyzable Silane Compound as Raw Material for Ink Repellent (E))

Compound (ex-11) corresponding to hydrolyzable silane compound (s1): F(CF₂)₆CH₂CH₂Si(OCH₃)₃ (prepared by a known method).

Compound (ex-12) corresponding to hydrolyzable silane compound (s1): F(CF₂)₈CH₂CH₂Si(OCH₃)₃ (prepared by a known method).

Compound (ex-13) corresponding to hydrolyzable silane compound (s1): F(CF₂)₄CH₂CH₂Si(OCH₃)₃ (prepared by a known method).

Compound (ex-21) corresponding to hydrolyzable silane compound (s2): Si(OC₂H₅)₄.

Compound (ex-31) corresponding to hydrolyzable silane compound (s3): CH₂═CHCOO(CH₂)₃Si(OCH₃)₃.

Compound (ex-41) corresponding to hydrolyzable silane compound (s4): (CH₃)₃SiOCH₃.

Compound (ex-42) corresponding to hydrolyzable silane compound (s4): trimethoxyphenyl silane.

Compound (ex-43) corresponding to hydrolyzable silane compound (s4): triethoxyphenyl silane.

### (Raw Material for Ink Repellent (E2))

C6FMA: CH₂═C(CH₃)COOCH₂CH₂(CF₂)₆F

C4α-Cl acrylate: CH₂═C(Cl)COOCH₂CH₂(CF₂)₄F

MAA: methacrylic acid

2-HEMA: 2-hydroxyethyl methacrylate

IBMA: isobornyl methacrylate

V-65: (2,2′-azobis(2,4-dimethylvaleronitrile))

n-DM: n-dodecyl mercaptan

BEI: 1,1-(bisacryloyloxymethyl)ethyl isocyanate.

AOI: 2-acryloyloxyethyl isocyanate.

DBTDL: dibutyltin dilaurate

TBQ: t-butyl-p-benzoquinone

MEK: 2-butanone

### (Crosslinking Agent (F))

F-1: dipentaerythritol hexaacrylate.

F-2: A mixed product of pentaerythritol acrylate, dipentaerythritol acrylate, tripentaerythritol acrylate and tetrapentaerythritol acrylate.

### (Thiol Compound (G))

PE-1: pentaerythritol tetrakis(3-mercapto butyrate).

### (Phosphoric Acid Compound (H))

H-1: mono(2-methacryloyloxyethyl) caproate acid phosphate.

H-2: phenylphosphonic acid.

### (Solvent (J))

PGMEA: propylene glycol monomethyl ether acetate.

PGME: propylene glycol monomethyl ether.

EDM: diethylene glycol ethyl methyl ether.

IPA: 2-propanol.

EDGAC: diethylene glycol monoethyl ether acetate.

### Synthesis of Ink Repellent (E)

### Synthesis Example 1

### Preparation of Ink Repellent (E1-1) Solution

Into a three-necked flask of 1,000 cm³ equipped with a stirrer, compound (ex-11), compound (ex-21) and compound (ex-31) were put to obtain a hydrolyzable silane compound mixture. Then, PGME was put into the mixture to prepare a raw material solution.

To the obtained raw material solution, a 1% aqueous hydrochloric acid solution was dropwise added. After completion of the dropwise addition, the mixture was stirred for 5 hours at 40° C., to obtain a PGME solution of ink repellent (E1-1) (concentration of ink repellent (E1-1): 10 mass %).

Further, after the completion of the reaction, the components of the reaction solution were measured by using gas chromatography, and it was confirmed that the respective compounds as raw materials became below the detection limits. The charged amounts of raw material hydrolyzable silane compounds used in the preparation of the obtained ink repellent (E1-1), etc. are shown in Table 1.

### Synthesis Examples 2 to 10

### Syntheses of Ink Repellents (E1-2) to (E1-10)

A solution (concentration of compounds in each case: 10 mass %) of each of ink repellents (E1-2) to (E1-10) was obtained in the same manner as in Synthesis Example 1, except that the raw material composition was as shown in Table 1.

Mn, Mw, the content of fluorine atoms, the content of C═C and the acid value, of the ink repellent obtained in each of Synthesis Examples 1 to 10, were measured, and the results are shown in Table 2.

TABLE 1

| Synthesis Example | | 1 | 2 | 3 | 4 | 5 | 6 | 7 | 8 | 9 | 10 |
|---|---|---|---|---|---|---|---|---|---|---|---|
| Ink repellent (E) | | (E1-1) | (E1-2) | (E1-3) | (E1-4) | (E1-5) | (E1-6) | (E1-7) | (E1-8) | (E1-9) | (E1-10) |
| Charged | Compound (ex-11) | 15 | 10.5 | 15 | 15 | 15 | 0 | 0 | 15 | 15 | 15 |
| amount of | Compound (ex-12) | 0 | 0 | 0 | 0 | 0 | 15 | 0 | 0 | 0 | 0 |
| silane | Compound (ex-13) | 0 | 0 | 0 | 0 | 0 | 0 | 15 | 0 | 0 | 0 |
| compound | Compound (ex-21) | 20 | 70.1 | 16.7 | 23.3 | 23.3 | 19.2 | 29.6 | 20 | 16.7 | 23.3 |
| or the like | Compound (ex-31) | 27 | 0 | 18.8 | 17.5 | 17.5 | 14.4 | 22.2 | 27 | 18.8 | 17.5 |
| (g) | Compound (ex-41) | 0 | 0 | 8.4 | 0 | 0 | 0 | 0 | 0 | 8.4 | 0 |
| | Compound (ex-42) | 0 | 0 | 0 | 7.2 | 0 | 0 | 0 | 0 | 0 | 7.2 |
| | Compound (ex-43) | 0 | 0 | 0 | 0 | 7.8 | 6.4 | 9.9 | 0 | 0 | 0 |
| | PGME | 284.3 | 0 | 0 | 262.9 | 281.3 | 255.6 | 321.1 | 284.3 | 0 | 262.9 |
| | PGMEA | 0 | 160 | 0 | 0 | 0 | 0 | 0 | 0 | 0 | 0 |
| | IPA | 0 | 0 | 269.2 | 0 | 0 | 0 | 0 | 0 | 269.2 | 0 |
| | 1% hydrochloric acid | 30 | 50.9 | 26.7 | 0 | 0 | 0 | 0 | 0 | 0 | 0 |
| | aqueous solution | | | | | | | | | | |
| | 1% nitric acid aqueous solution | 0 | 0 | 0 | 30.8 | 30.8 | 25.4 | 39.2 | 0 | 0 | 0 |
| | 1% sodium hydroxide | 0 | 0 | 0 | 0 | 0 | 0 | 0 | 30 | 26.7 | 0 |
| | aqueous solution | | | | | | | | | | |
| | 1% TMAH aqueous solution | 0 | 0 | 0 | 0 | 0 | 0 | 0 | 0 | 0 | 30.8 |
| Charged | Compound (ex-11) | 0.13 | 0.06 | 0.14 | 0.13 | 0.13 | 0.00 | 0.00 | 0.13 | 0.14 | 0.13 |
| molar | Compound (ex-12) | 0.00 | 0.00 | 0.00 | 0.00 | 0.00 | 0.13 | 0.00 | 0.00 | 0.00 | 0.00 |
| ratio of | Compound (ex-13) | 0.00 | 0.00 | 0.00 | 0.00 | 0.00 | 0.00 | 0.13 | 0.00 | 0.00 | 0.00 |
| silane | Compound (ex-21) | 0.39 | 0.94 | 0.34 | 0.45 | 0.45 | 0.45 | 0.45 | 0.39 | 0.34 | 0.45 |
| compound | Compound (ex-31) | 0.47 | 0.00 | 0.34 | 0.30 | 0.30 | 0.30 | 0.30 | 0.47 | 0.34 | 0.30 |
| | Compound (ex-41) | 0.00 | 0.00 | 0.18 | 0.00 | 0.00 | 0.00 | 0.00 | 0.00 | 0.18 | 0.00 |
| | Compound (ex-42) | 0.00 | 0.00 | 0.00 | 0.12 | 0.00 | 0.00 | 0.00 | 0.00 | 0.00 | 0.12 |
| | Compound (ex-43) | 0.00 | 0.00 | 0.00 | 0.00 | 0.12 | 0.12 | 0.12 | 0.00 | 0.00 | 0.00 |

### Synthesis Example 11

### Synthesis of Ink Repellent (E2-1)

Into an autoclave having an internal capacity of 1,000 cm³ and equipped with a stirrer, 415.1 g of MEK, 81.0 g of C6FMA, 18.0 g of MAA, 81.0 g of 2-HEMA, 5.0 g of polymerization initiator V-65 and 4.7 g of n-DM were charged and polymerized at 50° C. for 24 hours with stirring under a nitrogen atmosphere, and further heated at 70° C. for 5 hours, to deactivate the polymerization initiator and to obtain a solution of a copolymer. The copolymer had Mn of 5,540 and Mw of 13,200.

Then, into an autoclave having an internal capacity of 300 cm³ and equipped with a stirrer, 130.0 g of the above copolymer solution, 33.5 g of BEI, 0.13 g of DBTDL and 1.5 g of TBQ were charged and reacted at 40° C. for 24 hours with stirring, to synthesize a crude polymer. The obtained solution of the crude polymer was purified by reprecipitation by addition of hexane and then vacuum dried to obtain 65.6 g of ink repellent (E2-1).

### (Ink-Repellent (E2-2))

As ink repellent (E2-2), Megafac RS102 (trade name, manufactured by DIC Corporation: a polymer having a repeating unit represented by the following formula (E2F), n/m=3 to 4) was prepared.

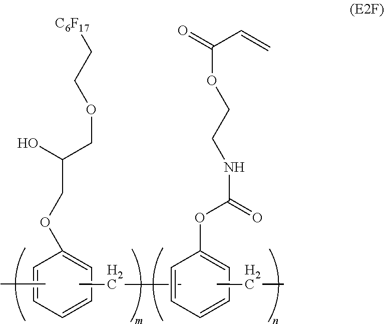

### Synthesis Example 12

### Synthesis of Ink Repellent (E2-3)

Into an autoclave having an internal capacity of 1,000 cm³ and equipped with a stirrer, 317.5 g of C4α-Cl acrylate, 79.4 g of MAA, 47.7 g of IBMA, 52.94 g of 2-HEMA, 4.6 g of n-DM and 417.7 g of MEK were charged and polymerized at 50° C. for 24 hours with stirring under a nitrogen atmosphere, and further heated at 70° C. for 5 hours to deactivate the polymerization initiator and to obtain a solution of a copolymer. The copolymer had Mn of 5,060 and Mw of 8,720. The solid content concentration was measured and found to be 30 wt %.

Then, into an autoclave having an internal capacity of 300 cm³ and equipped with a stirrer, 130.0 g of the above solution of the copolymer, 3.6 g (0.8 equivalent to the hydroxyl groups of the copolymer) of AOI, 0.014 g of DBTDL and 0.18 g of TBQ were charged and reacted at 40° C. for 24 hours with stirring, to synthesize a crude polymer. The obtained solution of the crude polymer was purified by reprecipitation by addition of hexane and then vacuum dried to obtain 35.8 g of ink repellent (E2-3).

Mn, Mw, the content of fluorine atoms, the content of C═C and the acid value, of each of ink repellents (E2-1) to (E2-3), are shown in Table 2.

TABLE 2

| | | | | Content | | |
|---|---|---|---|---|---|---|
| Syn- | | | | of fluo- | Content | |
| thetic | Ink | | | rine | of | |
| Exam- | repel- | | | atoms | C═C | Acid value |
| ple | lent | Mn | Mw | (wt %) | (mmol/g) | (mgKOH/g) |
| 1 | (E1-1) | 1,200 | 1,310 | 21.0 | 3.06 | — |
| 2 | (E1-2) | 1,330 | 1,560 | 19.0 | 0.00 | — |
| 3 | (E1-3) | 1,020 | 1,180 | 23.5 | 2.27 | — |
| 4 | (E1-4) | 1,030 | 1,150 | 22.2 | 2.09 | — |
| 5 | (E1-5) | 1,040 | 1,170 | 21.1 | 1.98 | — |
| 6 | (E1-6) | 950 | 1,090 | 25.4 | 1.83 | — |
| 7 | (E1-7) | 1,010 | 1,130 | 15.9 | 2.17 | — |
| 8 | (E1-8) | 1,330 | 1,520 | 21.0 | 3.06 | — |
| 9 | (E1-9) | 1,240 | 1,430 | 23.5 | 2.27 | — |
| 10 | (E1-10) | 1,360 | 1,650 | 22.2 | 2.09 | — |
| 11 | (E2-1) | 7,540 | 16,200 | 14.8 | 3.73 | 35.1 |
| — | (E2-2) | 5,700 | 8,800 | 19.0 | 2.86 | 0 |
| 12 | (E2-3) | 8,000 | 10,600 | 28.0 | 0.60 | 93.3 |

### [Ex. 1]

### (Production of Negative Photosensitive Resin Composition)

Into a stirring vessel of 200 cm³, 0.16 g of the (E1-1) solution obtained in the above Example 1 (containing 0.016 g of ink-repellent agent (E1-1) as solid content, and the rest being solvent PGME), 15.1 g of A-21 (solid content of 10.3 g, and the rest being solvent EDGAC), 1.5 g of IR907, 1.3 g of EAB, 1.3 g of C-1, 0.011 g of MHQ, 10.4 g of F-1, 65.2 g of PGMEA, 2.5 g of IPA and 2.5 g of water were put and stirred for 5 hours to produce a negative photosensitive resin composition. In Table 3, the solid content concentration, the contents (composition) of the respective components in the solid content and the contents (composition) of the respective components in the solvent, are shown.

With respect to the ink repellent (E1-1), the solid content is calculated to be 0.018 g from the charged amount, but the hydrolyzable groups will be detached to form methanol, ethanol, etc., and therefore, the solid content actually becomes lower than 0.018 g. It is difficult to determine how much of hydrolyzable groups will be detached, and therefore, on the assumption that substantially all of the hydrolyzable groups will be detached, the solid content is assumed to be 0.016 g.

### (Production of Cured Resin Film and Partition Walls)

A glass substrate of 10 cm square was ultrasonically cleaned for 30 seconds with ethanol and then subjected to UV/03 treatment for 5 minutes. For the UV/03 treatment, PL2001 N-58 (manufactured by Sen Engineering Co., Ltd.) was used as an UV/O₃ generator. Optical power (light output) of 254 nm conversion was 10 mW/cm². This device was used also in all of the following UV/03 treatments.

On the glass substrate surface after the washing, using a spinner, the above negative photosensitive resin composition was applied and then dried at 100° C. for 2 minutes on a hot plate to form a dried film having a thickness of 2.4 μm. To the obtained dried film, UV light of an ultra-high pressure mercury lamp, with an exposure power (exposure output) of 25 mW/cm² as calculated as 365 nm, was applied collectively over the entire surface, via a photomask having an opening pattern (light-shielding portion being 100 μm×200 μm, light transmitting portion being a grid pattern of 20 μm). At the time of exposure, light of 330 nm or less was cut. Further, the distance between the dried film and the photomask was adjusted to be 50 μm. In each Ex., the exposure conditions were such that the exposure time was four seconds, and the exposure amount was 100 mJ/cm².

Then, the glass substrate after the above exposure treatment was developed by being immersed for 40 seconds in a 2.38 mass % tetramethylammonium hydroxide aqueous solution, and unexposed portions were washed away by water and dried. Then, by heating at 230° C. for 60 minutes on a hot plate, a cured film (partition walls) having a pattern corresponding to the opening pattern of the photomask, was obtained.

Further, a dried film was formed on a glass substrate surface in the same manner as described above, and without using a photomask, the dried film was exposed under the same conditions as the above exposure conditions, and then, by heating at 230° C. for 60 minutes on a hot plate, a glass substrate with a cured resin film was obtained.

### [Ex. 2 to 18]

A negative photosensitive resin composition, a cured resin film and partition walls were produced in the same manner as in the above Ex.1, except that the negative photosensitive resin composition was changed to have the composition as shown in Tables 3 to 5.

### (Evaluations)

With respect to the negative photosensitive resin compositions, the cured resin layers and the partition walls obtained in Ex. 1 to 18, the following evaluations were conducted. The results are shown in the lower columns in Tables 3 to 5.

### <PCT Adhesion>

With respect to the cured resin film-attached glass substrate obtained as described above, the cured resin film was cross-cut by a cutter, so that the number of squares would be 25 at 2 mm intervals. Then, a PCT (pressure cooker) test was conducted by exposing this glass substrate for 24 hours under the conditions of 121° C., 100RH % and 2 atm. On the cured resin film of the cured resin film-attached glass substrate after the test, a pressure-sensitive adhesive tape (manufactured by Nichiban Co., Ltd., trade name: Cellotape (registered trademark)) was adhered to the portion where squares were formed by a cutter, and immediately thereafter, the adhesive tape was peeled off. The adhesion state of the cured resin film was evaluated on such a basis that a case where the number of peeled squares was small (a case where the number of remaining squares was at least 60%) was regarded as ◯ (good), and a case where the number of peeled squares was large (a case where the number of remaining squares was less than 60%) was regarded as x (no good).

### <C/In Ratio of Development Residue by XPS>

Instead of the above glass substrate, using an ITO substrate having an ITO layer on a glass substrate, and by using the negative photosensitive resin composition in each of Ex. 1 to 18, partition walls were formed on the ITO layer in the same manner as described above. With respect to the central portion of the opening sections in the obtained partition walls-attached ITO substrate, a surface analysis was conducted by X-ray photoelectron spectroscopy (XPS) under the following conditions. A case where the C/In value (the value of the ratio of the indium atom concentration to the carbon atom concentration) at the opening surface measured by XPS was less than 7 was regarded as “⊚” (excellent), a case where it was 7 to 12 was regarded as “◯” (good) and a case where it was more than 12 was regarded as “x” (no good).

### [XPS Conditions]

Apparatus: manufactured by ULVAC-PHI, Inc., Quantera-SXM X-ray source: Al Kα, X-ray beam size: about 20 μmφ, measurement area: about 20 μmφ

Detection angle: 45° from the sample surface, measured peak: C1s, measuring time (as Acquired Time): less than 5 minutes, analysis software: MultiPak

### <Ink Repellency on Top Surface of Partition Walls>

The PGMEA contact angle on the top surface of partition walls obtained as described above was measured by the above method.

◯: contact angle of at least 40°, x: contact angle of less than 40°

### <Pattern Linearity>

The partition walls obtained by using the photomask having a light transmitting portion with a width of 20 μm as described above, were observed by a microscope, whereupon a case where irregularities were not observed, was regarded as ◯ (good), and a case where irregularities were observed, was regarded as x (no good).

TABLE 3

| | | | | Ex. 1 | Ex. 2 | Ex. 3 | Ex. 4 | Ex. 5 | Ex. 6 | Ex. 7 | Ex. 8 |
|---|---|---|---|---|---|---|---|---|---|---|---|
| Composition | Composition | Alkali-soluble resin | A-21 | 41.3 | | | | 42.6 | 42.2 | 42.6 | 41.3 |
| of negative | of solid | (A) | A-22 | | 41.3 | | | | | | |
| photosensitive | content | | A-23 | | | 44.6 | | | | | |
| resin | (mass %) | | A-24 | | | | 44.6 | | | | |
| composition | | Photopolymerization | IR907 | 5.9 | | | | 6.1 | 6.1 | 6.1 | 5.9 |
| | | initiator (B) | IR369 | | 5.9 | | | | | | |
| | | | OXE01 | | | 3.9 | | | | | |
| | | | OXE02 | | | | 3.9 | | | | |
| | | Photopolymerization | EAB | 5.2 | 5.2 | | | 5.4 | 5.3 | 5.4 | 5.2 |
| | | initiator (B): Non- | Tinuvin329 | | | | | | | | |
| | | reactive ultraviolet | | | | | | | | | |
| | | absorber | | | | | | | | | |
| | | Reactive ultraviolet | C-1 | 5.2 | 5.2 | 5.6 | 5.6 | 2.2 | 2.1 | 2.2 | 5.2 |
| | | absorber (C) | | | | | | | | | |
| | | polymerization | MHQ | 0.043 | 0.043 | 0.046 | 0.046 | 0.044 | 0.044 | 0.044 | |
| | | inhibitor (D) | BHT | | | | | | | | 0.043 |
| | | | MEHQ | | | | | | | | |
| | | Ink repellent (E) | (E1-1) | 0.63 | | | | | | | |
| | | | (E1-2) | | 0.63 | | | | | | |
| | | | (E1-3) | | | 0.68 | | | | | |
| | | | (E1-4) | | | | 0.68 | | | | |
| | | | (E1-5) | | | | | 0.65 | | | |
| | | | (E1-6) | | | | | | 0.64 | | |
| | | | (E1-7) | | | | | | | 0.65 | |
| | | | (E1-8) | | | | | | | | 0.63 |
| | | | (E1-9) | | | | | | | | |
| | | | (E1-10) | | | | | | | | |
| | | | (E2-1) | | | | | | | | |
| | | | (E2-2) | | | | | | | | |
| | | | (E2-3) | | | | | | | | |
| | | Cross-linking agent | F-1 | 41.7 | 41.7 | 45.1 | 45.1 | 32.3 | 42.6 | 43.0 | 41.7 |
| | | (F) | F-2 | | | | | | | | |
| | | Thiol compound (G) | PE-1 | | | | | 10.8 | | | |
| | | Phosphoric acid | H-1 | | | | | | | | |
| | | compound (H) | H-2 | | | | | | 1.1 | | |
| | Solid content concentration (mass %) | | | 25 | 25 | 25 | 25 | 25 | 25 | 25 | 25 |
| | Solvent | Solvent (J) | PGMEA | 86.9 | 7.5 | 66.7 | 66.7 | 86.9 | | 90.9 | 90.9 |
| | composition | | PGME | | 52.5 | | | | 80.2 | 2.7 | 2.7 |
| | (mass %) | | EDM | | 26.7 | 33.3 | 33.3 | | 13.3 | | |
| | | | IPA | 3.3 | 6.7 | | | 3.3 | | | |
| | | | Water | 3.3 | 6.7 | | | 3.3 | | | |
| | | | EDGAC | 6.4 | | | | 6.4 | 6.4 | 6.4 | 6.4 |

| Evaluation | PCT adhesion | ◯ | ◯ | ◯ | ◯ | ◯ | ◯ | ◯ | ◯ |
|---|---|---|---|---|---|---|---|---|---|
| | C/In ratio in development residue | ⊚ | ⊚ | ⊚ | ⊚ | ⊚ | ⊚ | ⊚ | ⊚ |
| | by XPS | | | | | | | | |
| | Contact angle | ◯ | ◯ | ◯ | ◯ | ◯ | ◯ | ◯ | ◯ |
| | Pattern linearity | ◯ | ◯ | ◯ | ◯ | ◯ | ◯ | ◯ | ◯ |

TABLE 4

| | | | | Ex. 9 | Ex. 10 | Ex. 11 | Ex. 12 | Ex. 13 | Ex. 14 | Ex. 15 |
|---|---|---|---|---|---|---|---|---|---|---|
| Composition | Composition | Alkali-soluble resin | A-21 | 41.3 | 41.3 | 41.3 | 42.6 | 44.6 | 44.6 | 42.6 |
| of negative | of solid | (A) | A-22 | | | | | | | |
| photosensitive | content | | A-23 | | | | | | | |
| resin | (mass %) | | A-24 | | | | | | | |
| composition | | Photopolymerization | IR907 | 5.9 | 5.9 | 5.9 | 6.1 | | | 6.1 |
| | | initiator (B) | IR369 | | | | | | | |
| | | | OXE01 | | | | | 3.9 | | |
| | | | OXE02 | | | | | | 3.9 | |
| | | Photopolymerization | EAB | 5.2 | 5.2 | 5.2 | 5.4 | | | 5.4 |
| | | initiator (B): Non- | Tinuvin329 | | | | | | | |
| | | reactive ultraviolet | | | | | | | | |
| | | absorber | | | | | | | | |
| | | Reactive ultraviolet | C-1 | 5.2 | 5.2 | 5.2 | 2.2 | 5.6 | 5.6 | 2.2 |
| | | absorber (C) | | | | | | | | |
| | | polymerization | MHQ | | 0.043 | 0.043 | 0.044 | 0.046 | 0.046 | 0.001 |
| | | inhibitor (D) | BHT | | | | | | | |
| | | | MEHQ | 0.043 | | | | | | |
| | | Ink repellent (E) | (E1-1) | | | | | | | |
| | | | (E1-2) | | | | | | | |
| | | | (E1-3) | | | | | | | |
| | | | (E1-4) | | | | | | | |
| | | | (E1-5) | | | | | | | 0.65 |
| | | | (E1-6) | | | | | | | |
| | | | (E1-7) | | | | | | | |
| | | | (E1-8) | | | | | | | |
| | | | (E1-9) | 0.63 | | | | | | |
| | | | (E1-10) | | 0.63 | | | | | |
| | | | (E2-1) | | | 0.63 | 0.65 | | | |
| | | | (E2-2) | | | | | 0.68 | | |
| | | | (E2-3) | | | | | | 0.68 | |
| | | Cross-linking agent | F-1 | 41.7 | | 41.7 | 43.0 | 45.1 | 45.1 | 32.3 |
| | | (F) | F-2 | | 41.7 | | | | | |
| | | Thiol compound (G) | PE-1 | | | | | | | 10.8 |
| | | Phosphoric acid | H-1 | | | | | | | |
| | | compound (H) | H-2 | | | | | | | |
| | Solid content concentration (mass %) | | | 25 | 25 | 25 | 25 | 25 | 25 | 25 |
| | Solvent | Solvent (J) | PGMEA | 90.9 | 86.9 | 86.9 | 90.9 | | | 86.9 |
| | composition | | PGME | 2.7 | | | 2.7 | 80.2 | 80.2 | |
| | (mass %) | | EDM | | | | | 13.3 | 13.3 | |
| | | | IPA | | 3.3 | 3.3 | | | | 3.3 |
| | | | Water | | 3.3 | 3.3 | | | | 3.3 |
| | | | EDGAC | 6.4 | 6.4 | 6.4 | 6.4 | 6.4 | 6.4 | 6.4 |

| Evaluation | PCT adhesion | ◯ | ◯ | ◯ | ◯ | ◯ | ◯ | ◯ |
|---|---|---|---|---|---|---|---|---|
| | C/In ratio in development residue | ⊚ | ⊚ | ⊚ | ⊚ | ⊚ | ⊚ | ◯ |
| | by XPS | | | | | | | |
| | Contact angle | ◯ | ◯ | ◯ | ◯ | ◯ | ◯ | ◯ |
| | Pattern linearity | ◯ | ◯ | ◯ | ◯ | ◯ | ◯ | ◯ |

TABLE 5

| | | | | Ex. 16 | Ex. 17 | Ex. 18 |
|---|---|---|---|---|---|---|
| Composition | Composition | Alkali-soluble resin | A-21 | | 40.9 | 41.3 |
| of negative | of solid | (A) | A-22 | | | |
| photosensitive | content | | A-23 | | | |
| resin | (mass %) | | A-24 | 57.6 | | |
| composition | | Photopolymerization | IR907 | | 5.9 | 5.9 |
| | | initiator (B) | IR369 | | | |
| | | | OXE01 | 2.1 | | |
| | | | OXE02 | | | |
| | | Photopolymerization | EAB | | 5.2 | 5.2 |
| | | initiator (B): Non- | Tinuvin329 | | | 5.2 |
| | | reactive ultraviolet | | | | |
| | | absorber | | | | |
| | | Reactive ultraviolet | C-1 | | 5.2 | |
| | | absorber (C) | | | | |
| | | polymerization | MHQ | 0.08 | | 0.043 |
| | | inhibitor (D) | BHT | | | |
| | | | MEHQ | | | |
| | | Ink repellent (E) | (E1-1) | 2.12 | | 0.63 |
| | | | (E1-2) | | | |
| | | | (E1-3) | | | |
| | | | (E1-4) | | | |
| | | | (E1-5) | | | |
| | | | (E1-6) | | | |
| | | | (E1-7) | | | |
| | | | (E1-8) | | | |
| | | | (E1-9) | | | |
| | | | (E1-10) | | | |
| | | | (E2-1) | | 0.619 | |
| | | | (E2-2) | | | |
| | | | (E2-3) | | | |
| | | Cross-linking agent | F-1 | | 41.3 | 41.7 |
| | | (F) | F-2 | 38.10 | | |
| | | Thiol compound (G) | PE-1 | | | |
| | | Phosphoric acid | H-1 | | 1.0 | |
| | | compound (H) | H-2 | | | |
| | Solid content concentration (mass %) | | | 25 | 25 | 25 |
| | Solvent | Solvent (J) | PGMEA | 66.7 | 7.5 | 86.9 |
| | composition | | PGME | | 52.5 | |
| | (mass %) | | EDM | 33.3 | 26.7 | |
| | | | IPA | | 6.7 | 3.3 |
| | | | Water | | 6.7 | 3.3 |
| | | | EDGAC | | | 6.4 |

| Evaluation | PCT adhesion | X | ◯ | X |
|---|---|---|---|---|
| | C/In ratio in development residue | X | X | ⊚ |
| | by XPS | | | |
| | Contact angle | ◯ | ◯ | ◯ |
| | Pattern linearity | ◯ | ◯ | ◯ |

As is evident from Tables 3 to 5, in the negative photosensitive resin compositions in Ex. 1 to 15 corresponding to Examples of the present invention, the reactive UV absorber (C) and the polymerization inhibitor (D) are used in combination, whereby in forming the partition walls on a substrate, curing is improved at the substrate interface so that the PCT adhesion is excellent, and the top surface of partition walls has good ink repellency, and the reaction at opening sections is prevented to reduce the residue, whereby the C/In ratio of development residue by XPS is good.

Whereas, in the negative photosensitive resin compositions in Comparative Examples 16 to 18, only either one of the reactive ultraviolet absorber (C) and the polymerization inhibitor (D) is contained in each case, whereby in forming partition walls on a substrate, curing is not improved at the substrate interface and the PCT adhesion is not good, whereby the shape retention of the partition walls themselves is difficult, and/or it is not possible to prevent the reaction at opening sections and to reduce the residue, whereby the C/In ratio of development residue by XPS is insufficient. Further, in Ex. 18, an ultraviolet absorber is used in combination with the polymerization inhibitor (D), but it is a non-reactive ultraviolet absorber i.e. not a reactive ultraviolet absorber (C), whereby the PCT adhesion is not good.

### INDUSTRIAL APPLICABILITY

The negative photosensitive resin composition of the present invention is useful as a composition for e.g. forming partition walls at the time of carrying out pattern printing by IJ method, in an organic EL device, a quantum dot display, a TFT array or a thin-film solar cell.

The partition walls of the present invention may be utilized as partition walls (banks) for pattern-printing of an organic layer such as a luminescent layer by IJ method in an organic EL element, or partition walls (banks) for pattern-printing a quantum dot layer, hole transporting layer, etc. by IJ method in a quantum dot display. The partition walls of the present invention may also be utilized as partition walls for pattern-printing a conductor pattern or a semiconductor pattern by IJ method in a TFT array.

The partition walls of the present invention may, for example, be utilized as partition walls for pattern-printing an organic semiconductor layer constituting a channel layer of TFT, a gate electrode, a source electrode, a drain electrode, a gate wiring and a source wiring by IJ method.

This application is a continuation of PCT Application No. PCT/JP2015/054323, filed on Feb. 17, 2015, which is based upon and claims the benefit of priority from Japanese Patent Application No. 2014-028800 filed on Feb. 18, 2014. The contents of those applications are incorporated herein by reference in their entireties.

What is claimed is:

1. A negative photosensitive resin composition for an organic EL element, a quantum dot display, a TFT array or a thin film solar cell, characterized by comprising an alkali-soluble resin or alkali-soluble monomer (A) having a photo-curable property, a photopolymerization initiator (B), a reactive ultraviolet absorber (C), a polymerization inhibitor (D) and an ink repellent (E).

2. The negative photosensitive resin composition according to claim 1, wherein in the total solid content in the negative photosensitive resin composition, the content of the reactive ultraviolet absorber (C) is from 0.01 to 20 mass %, and the content of the polymerization inhibitor (D) is from 0.001 to 1 mass %.

3. The negative photosensitive resin composition according to claim 1, wherein the reactive ultraviolet absorber (C) is a reactive ultraviolet absorber (C1) having a benzophenone skeleton, a benzotriazole skeleton, a cyano acrylate skeleton or a triazine skeleton, and having an ethylenic double bond.

4. The negative photosensitive resin composition according to claim 3, wherein the reactive ultraviolet absorber (C1) is a compound represented by the following formula (C11): 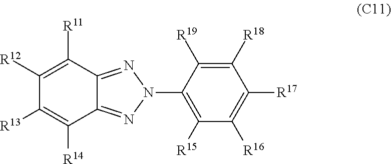
in the formula (C11), R¹¹ to R¹⁹ are each independently a hydrogen atom, a hydroxy group, a halogen atom or a monovalent substituted or unsubstituted hydrocarbon group which is bonded to the benzene ring directly or via an oxygen atom and which may have at least one member selected from an ethylenic double bond, an etheric oxygen atom and an ester bond, between carbon atoms, provided that at least one of R¹¹ to R¹⁹ has an ethylenic double bond.

5. The negative photosensitive resin composition according to claim 1, wherein the ink repellent (E) has fluorine atoms, and the content of fluorine atoms in the ink repellent (E) is from 1 to 40 mass %.

6. The negative photosensitive resin composition according to claim 1, wherein the ink repellent (E) is a compound having an ethylenic double bond.

7. The negative photosensitive resin composition according to claim 1, wherein the ink repellent (E) is a partially hydrolyzed condensate of a hydrolyzable silane compound.

8. A cured resin film for an organic EL element, a quantum dot display, a TFT array or a thin film solar cell, characterized by being formed by using the negative photosensitive resin composition as defined in claim 1.

9. Partition walls for an organic EL element, a quantum dot display, a TFT array or a thin film solar cell, which are formed to partition a substrate surface into a plurality of compartments for forming dots, and which are characterized by being made of the cured resin file as defined in claim 8.

10. An optical element having partition walls located between a plurality of dots and their adjacent dots on a substrate surface, the optical element being an organic EL element, a quantum dot display, a TFT array or a thin film solar cell, and characterized in that said partition walls are formed of the partition walls as defined in claim 9.

11. The optical element according to claim 10, wherein the dots are formed by an inkjet method.
